(19) United States
(12) Patent Application Publication
(10) Pub. No.: US 2025/0362517 A1
(43) Pub. Date: Nov. 27, 2025

(54) MICRO-LENS ARRAY-BASED LASER PROJECTION MODULE

(71) Applicant: JIAXING UPHOTON OPTOELECTRONICS TECHNOLOGY CO., LTD., Tongxiang City (CN)

(72) Inventors: Zhentao FAN, Tongxiang City (CN); Kehan TIAN, Tongxiang City (CN)

(21) Appl. No.: 18/877,205

(22) PCT Filed: Jun. 2, 2023
(86) PCT No.: PCT/CN2023/097970

§ 371 Date: Dec. 20, 2024

(30) Foreign Application Priority Data
Jun. 21, 2022 (CN) 202210708429.0

(51) Int. Cl. G02B 27/09; G01S 7/481; G02B 3/00; G02B 26/04; H01S 5/00; H01S 5/40

(52) U.S. Cl. CPC G02B 27/0922; G02B 3/0043; G02B 26/04; G02B 27/0961; H01S 5/0085; H01S 5/4075; G01S 7/4815

(57) ABSTRACT

A laser projection module includes an illumination light source and a micro-lens array. The micro-lens array includes a plurality of micro-lenses arranged at a first pitch P. In a working mode of projecting a spot array light field, a working distance D₁ of the micro-lens array relative to the light source satisfies the following equation:

$${D}_{1} = \frac{{NP}^{2}}{2 λ} + α f$$

where N is a positive integer, preferably N≤5; λ is the wavelength of light from the light source; α is a coefficient, 0<α≤1; and f is a focal length of the micro-lens. By selecting and optimizing the coefficient α for the focal length of the micro-lens, light energy of the spot array light field generated with the corresponding working distance is focused onto smaller spots, and thus contrast of laser spot array is improved.

This application claims the priority of the Chinese patent application filed with the China Patent Office on 21 Jun. 2022, with application Ser. No. 20/221,0708429.0 and invention title “MICRO-LENS ARRAY-BASED LASER PROJECTION MODULE”, the entire contents of which are incorporated by reference in this application.

### TECHNICAL FIELD

The present disclosure generally relates to three-dimensional sensing technology, particularly, to a laser projection module for being used in a three-dimensional sensing device.

### BACKGROUND

There are three main types of optical three-dimensional sensing technologies: binocular stereo vision, structured light technology, and TOF (Time of Flying) technology. Different technologies may have varied performances, and be suitable for different application scenarios. In the field of consumer electronics (such as mobile phones), structured light technology and TOF technology are currently the most widely used. Both structured light technology and TOF technology need to be implemented based on a laser projection module that can project a predetermined light field. Structured light technology needs to project a patterned light field. TOF technology usually uses a flood light field, and can also use a patterned light field, such as a laser spot array.

Most of the existing solutions for laser spot array projection turn laser beams emitted by vertical cavity surface emitting lasers (VCSELs) into collimated light by using a collimating lens and then form a spot array through diffraction of a diffractive optical element (DOE). However, such solutions require a collimating lens to collimate the laser such that the system solution is complex, the overall device is thick, and the cost is high. CN107429993B discloses a device for generating a laser spot array based on a micro-lens array, which simplifies the structure, and in particular, significantly reduces the thickness of the device, as compared to the existing solutions for laser spot array projection based on diffraction optical elements. However, the technology for generating structured light based on a micro-lens array is not without defects.

### SUMMARY

The object of the present disclosure is to provide a laser projection module, which at least partly overcomes the deficiencies in the prior art.

According to one aspect of the present disclosure, a laser projection module based on a micro-lens array is provided, and the laser projection module comprises an illumination light source and a first micro-lens array, the first micro-lens array comprising a plurality of first micro-lenses arranged in a first plane, and the plurality of first micro-lenses being arranged in a first array at a first pitch P, wherein the laser projection module is configured to have a first working mode; and in the first working mode, in a direction perpendicular to the first plane, the first micro-lens array has a first working distance D₁ relative to the illumination light source, and light from the illumination light source is modulated by the first micro-lens array to project a spot array light field on the target surface. The first working distance D₁ satisfies the following equation:

$${D}_{1} = \frac{{NP}^{2}}{2 λ} + α f$$

where N is a positive integer, preferably N≤5; λ is a wavelength of light from the illumination light source; α is a first coefficient, 0<α≤1; and f is a focal length of the first micro-lens.

Advantageously, the first micro-lens has an aspherical surface and has focal lengths f₁ and f₂ in two mutually perpendicular directions in the first plane, respectively, where f=(f₁+f₂)/2.

Advantageously, the first array is a rectangular array, a parallelogram array, or a regular hexagonal array.

Advantageously, the illumination light source comprises a plurality of light-emitting points arranged in a second plane, the second plane is parallel to the first plane, and the plurality of light-emitting points are arranged in a light source array at a light source spacing W, with cell structures of the light source array being polygons similar to cell structures of the first array.

Advantageously, the first pitch P and the light source spacing W satisfy the following equation: wW=pP, where w and p are positive integers without a common factor, and preferably, w=p=1.

In some embodiments, the laser projection module is further configured to have a second working mode; and in the second working mode, in a direction perpendicular to the first plane, the first micro-lens array has a second working distance D₂ relative to the illumination light source, and light from the illumination light source is modulated by the first micro-lens array to project a uniform light field on the target surface, wherein the second working distance D₂ satisfies the following equation:

$${D}_{2} = \frac{{MP}^{2}}{2 λ} + \frac{β {P}^{2}}{4 λ} + α f$$

where M is a non-negative integer, β is a second coefficient, and 0.8≤β≤1.2.

Advantageously, the second working distance is smaller than the first working distance.

Advantageously, the laser projection module is configured such that at least one of the illumination light source and the first micro-lens array is movable in a direction perpendicular to the first plane, so that the first micro-lens array switches between the first working distance and the second working distance relative to the illumination light source.

In other embodiments, the laser projection module can further comprise a second micro-lenses array, the second micro-lenses array comprising a plurality of second micro-lenses arranged in the first plane, and the plurality of second micro-lenses being arranged in a second array at a second pitch P′, wherein the laser projection module is further configured to have a second working mode; and in the second working mode, light from the illumination source is modulated by the second micro-lens array to project a uniform light field on the target surface.

Advantageously, the second pitch P′ satisfies the following equation:

$${D}_{1} = \frac{{M}^{′} {P}^{′2}}{2 λ} + \frac{{β}^{′} {P}^{′2}}{4 λ} + {α}^{′} {f}^{′}$$

where, M′ is a non-negative integer; f′ is a focal length of the second micro-lens; α′ is a third coefficient, 0<α′≤1; and β′ is a fourth coefficient, 0.8≤β′≤1.2.

Advantageously, in the first working mode, the illuminating light source faces the first micro-lens array; and in the second working mode, the illuminating light source faces the second micro-lens array.

Advantageously, the laser projection module is configured such that the illumination light source is movable parallel to the first plane and relative to the first micro-lens array and the second micro-lens array.

In the laser projection module according to embodiments of the present disclosure, the working distance from the micro-lens array to the illumination light source in the working mode for projecting the spot array light field further is determined, taking into account the influence of the focal length of the micro-lens. By appropriately selecting and optimizing the influence coefficient a for the focal length of the micro-lens, the light energy of the spot array light field generated with the corresponding working distance can be focused onto significantly smaller light spots, and thus the contrast of the laser spot array is greatly improved.

### BRIEF DESCRIPTION OF THE DRAWINGS

Other features, objects, and advantages of the present disclosure will become more apparent by reading the following detailed description of non-limitative embodiments with reference to the following drawings.

FIG. 1 is a schematic diagram of a laser projection module according to Embodiment 1 of the present disclosure;

FIG. 2 is a schematic diagram of examples of a micro-lens array and a light source array that can be used for the laser projection module shown in FIG. 1;

FIG. 3 shows simulation diagrams of a single light spot in a spot array light field obtained through simulation with different values of parameter α based on the laser projection module shown in FIG. 1;

FIG. 4 shows diagrams of the spot array light fields obtained in the calculation examples shown in FIG. 3 with α=0 and α=0.9;

FIGS. 5, 6, and 7 respectively show simulation diagrams of a single light spot in a spot array light field obtained through simulation with different values of parameter α based on the laser projection module shown in FIG. 1 under different parameter conditions;

FIG. 8 is a schematic diagram of a laser projection module according to Embodiment 2 of the present disclosure;

FIG. 9 shows simulation diagrams of a spot array light field and a uniform light field obtained based on the laser projection module shown in FIG. 8;

FIG. 10 is a schematic diagram of a laser projection module according to Embodiment 3 of the present disclosure; and

FIG. 11 is a schematic diagram of a variant of the laser projection module shown in FIG. 10.

### DETAILED DESCRIPTION

The present disclosure will be further described in detail in conjunction with drawings and embodiments. It should be understood that the specific embodiments described herein are only used to explain the related disclosure, but not to limit the disclosure. For the convenience of description, only the parts related to the disclosure are shown in the drawings. It should be noted that the embodiments in the present application and the features of the embodiments may be combined with each other without conflict.

This application is put forward based on the following findings: in the device for generating laser spot array disclosed in CN107429993B, strict restrictions are imposed on the relationship between a lens pitch of a micro-lens array, the distance from the micro-lens array to a light source, and wavelength; however, experiments show that under this strictly restricted relationship, the contrast of the laser spot array is not optimal; and further research reveals that the contrast of the laser spot array is also affected by the focal length of the micro-lenses in the micro-lens array. Based on the above findings, improvements have been made to a laser spot array projection device based on a micro-lens array, and a new structural relationship has been proposed to effectively improve the spot array contrast. The following will be introduced in conjunction with specific embodiments with reference to the accompanying drawings.

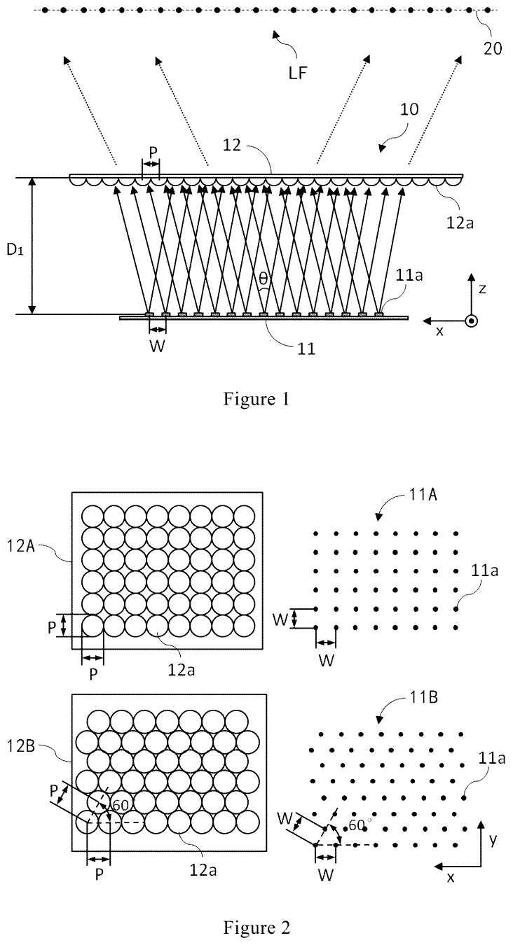

FIG. 1 is a schematic diagram of a laser projection module according to Embodiment 1 of the present disclosure. As shown in FIG. 1, the laser projection module 10 comprises an illumination light source 11 and a micro-lens array 12. The illumination light source 11 can comprise a single light-emitting point or a plurality of light-emitting points. In the example shown in FIG. 1, the illumination light source 11 comprises a plurality of light-emitting points 11a. The micro-lens array 12 comprises a plurality of micro-lenses 12a arranged in a plane (x-y plane shown in FIG. 1), and the plurality of micro-lenses 12a are arranged in an array at a predetermined pitch P (see arrays 12A and 12B shown in FIG. 2). According to this embodiment, the laser projection module 10 is configured to have a working mode of projecting a spot array light field. Specifically, in the working mode of projecting the spot array light field, in a direction perpendicular to the x-y plane (z direction shown in FIG. 1), the micro-lens array 12 has a working distance D₁ relative to the illumination light source 11, so that light from the illumination light source 11 is modulated by the micro-lens array 12 to project a spot array light field LF on the target surface 20. According to the embodiment of the present disclosure, in the working mode of projecting a spot array light field, the working distance D₁ satisfies the following equation:

$${D}_{1} = \frac{{NP}^{2}}{2 λ} + α f$$

where N is a positive integer, preferably N≤5; λ is a wavelength of light from the illumination light source 11 (the working wavelength of the laser projection module); α is a coefficient, 0<α≤1; and f is a focal length of the micro-lens 12a.

In some implementations, the micro-lens 12a can have an aspherical surface, and thus have different focal lengths f₁ and f₂ in two mutually perpendicular directions in the x-y plane. For example, in the x-z plane, the micro-lens 12a has a focal length f₁; in the y-z plane, the micro-lens 12a has a focal length f₂. In the above case, in the laser projection module according to an embodiment of the present disclosure, the focal length f of the micro-lens 12a in the above equation can be taken as follows: f=(f₁+f₂)/2.

Only for purpose of illustration, FIG. 2 shows different arrangements of micro-lens arrays and light source arrays that can be used in the laser projection module 10. The upper left corner of FIG. 2 shows a micro-lens array 12 in the form of a rectangular array 12A, and the lower left corner shows a micro-lens array 12 in the form of a regular hexagonal array 12B. In addition to the form shown in FIG. 2, the micro-lens array used in the present invention can also be, for example, a parallelogram array.

According to the embodiment of the present disclosure, the illumination light source 11 can comprise the plurality of light-emitting points 11a. Preferably, the plurality of light-emitting points 11a are arranged in a light source array in another plane parallel to the plane where the micro-lens array 12 is located, such as the arrays 11A and 11B shown in the diagrams on the right side of FIG. 2, and cell structures (lattices) of the light source arrays 11A and 11B are polygons similar to cell structures of the rectangular micro-lens array 12 A and those of the regular hexagonal micro-lens array 12B shown on the left side of FIG. 2. More preferably, the pitch P of the micro-lenses 12a in the micro-lens array 12 and the spacing W (the light source spacing) between the light-emitting points in the illumination light source satisfy the following equation:

$$wW = pP$$

where w and p are positive integers without a common factor, and preferably, w=p=1.

In order to illustrate the technical effect of the laser projection module according to the embodiment of the present invention in improving the contrast of the laser spot array, data examples of simulation calculation are given below.

### Data Example 1

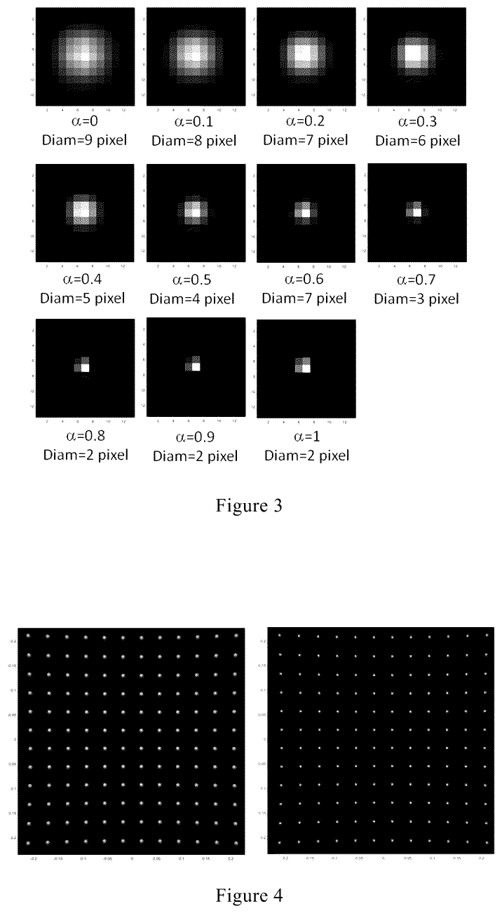

In Data Example 1, simulation is performed based on the laser projection module 10 shown in FIG. 1 with different values of the parameter α, and the distribution of the spot array light field is calculated. In Data Example 1, the working wavelength λ=940 nm; the illumination light source 11 and the micro-lens array 12 are both rectangular arrays, where P=W=39 μm, f=40 μm; N=2, α takes values of 11 points equally spaced from 0 to 1; diagrams of a single point light spot in the spot array light fields obtained by simulation calculation are shown in FIG. 3. As shown in FIG. 3, when α takes values of 0.8, 0.9 and 1, the diameter of a single point light spot is of the minimum value, which is 2 pixels. At this time, the midpoint α=0.9 can be selected as the optimal value. It can be seen that as compared to the point light spot having a diameter of 9 pixels when α=0, when α takes values of 0.8 to 1, the light spots on which light energy of the spot array light field generated with the corresponding working distance D₁ is focused, are significantly smaller, and thus the contrast of the laser spot array is greatly improved. In order to allow this effect be observed intuitively and more clearly, FIG. 4 further shows diagrams of the spot array light fields obtained when α=0 and α=0.9 in Data Example 1.

According to the embodiment of the present disclosure, in the laser projection module, the optimal value of the coefficient α used for determining the working distance D₁ between the micro-lens array 12 and the illumination light source 11 varies according to various parameters in the laser projection module. After reading this application, those skilled in the art can determine the optimal value of the coefficient α and the corresponding working distance by means of simulation or experiment as required in specific applications. For ease of understanding, Data Examples 2 to 4 are further given below, in which simulation calculations are conducted with different values of α under different parameter conditions.

### Data Example 2

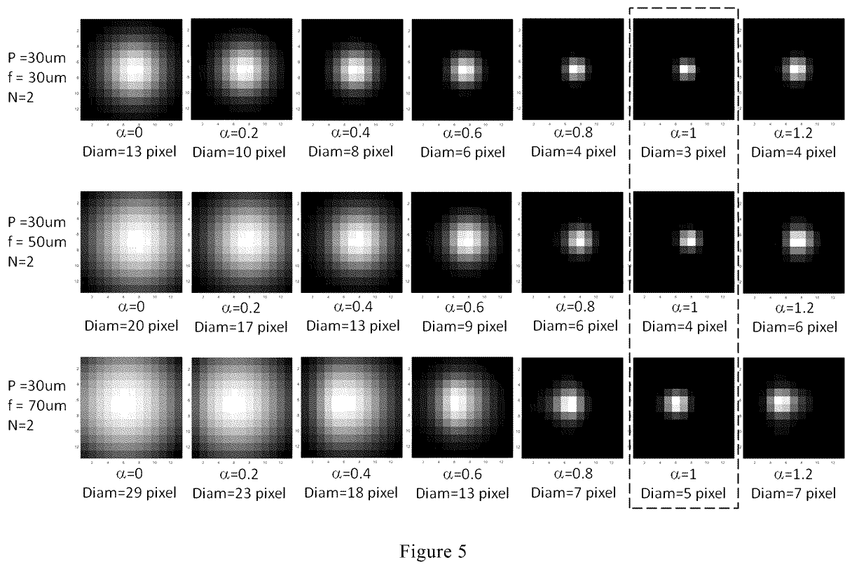

In Data Example 2, the working wavelength α=940 nm; the illumination light source 11 and the micro-lens array 12 are both rectangular arrays, where P=30 μm, W=30 μm; N=2; the focal length f of the micro-lens 12a takes values of 30 μm, 50 μm, and 70 μm, and α takes values of 7 points equally spaced from 0 to 1.2; and diagrams of a single point light spot in the spot array light fields obtained by simulation calculation are shown in FIG. 5.

As shown in FIG. 5, corresponding to the above different values of f, that is, 30 μm, 50 μm, and 70 μm, the diameter of a single point light spot is of the minimum values when α=1, which are 3 pixels, 4 pixels, and 5 pixels, respectively. It can be seen that under the above parameter conditions, α=1 is the optimal value. Similar to what is shown in FIG. 3, it can be seen that as compared to the diameter (13 pixels, 20 pixels, and 29 pixels respectively) of the point light spot when α=0, when α is 1, the light spots on which light energy of the spot array light field generated with the corresponding working distance D₁ is focused, are significantly smaller, which is beneficial to improving the contrast of the laser spot array.

### Data Example 3

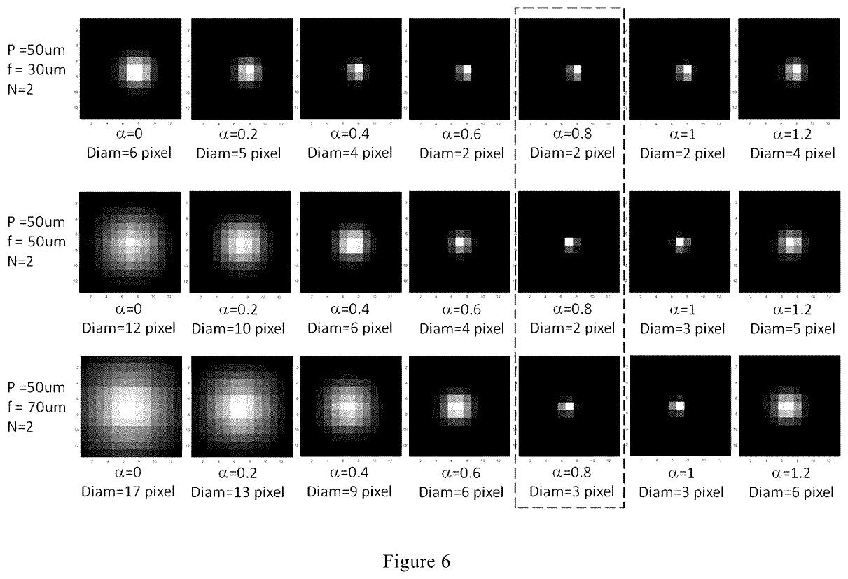

In Data Example 3, the working wavelength α=940 nm; the illumination light source 11 and the micro-lens array 12 are both rectangular arrays, where P=50 μm, W=50 82 m; N=2; the focal length f of the micro-lens 12a takes values of 30 μm, 50 μm, and 70 μm, and α takes values of 7 points equally spaced from 0 to 1.2; and diagrams of a single point light spot in the spot array light fields obtained by simulation calculation are shown in FIG. 6.

As shown in FIG. 6, corresponding to the above different values of f, that is, 30 μm, 50 μm, and 70 μm, the diameter of a single point light spot is of the minimum values when α=0.8, which are 2 pixels, 2 pixels, and 3 pixels, respectively. It can be seen that under the above parameter conditions, α=0.8 can be taken as the optimal value. Similar to what is shown in FIG. 3 and FIG. 5, it can be seen that as compared to the diameter (6 pixels, 12 pixels, and 17 pixels respectively) of the point light spot when α=0, when α is 0.8, the light spots on which the light energy of the spot array light field generated with the corresponding working distance D₁ is focused, are significantly smaller, which is beneficial to improving the contrast of the laser spot array.

### Data Example 4

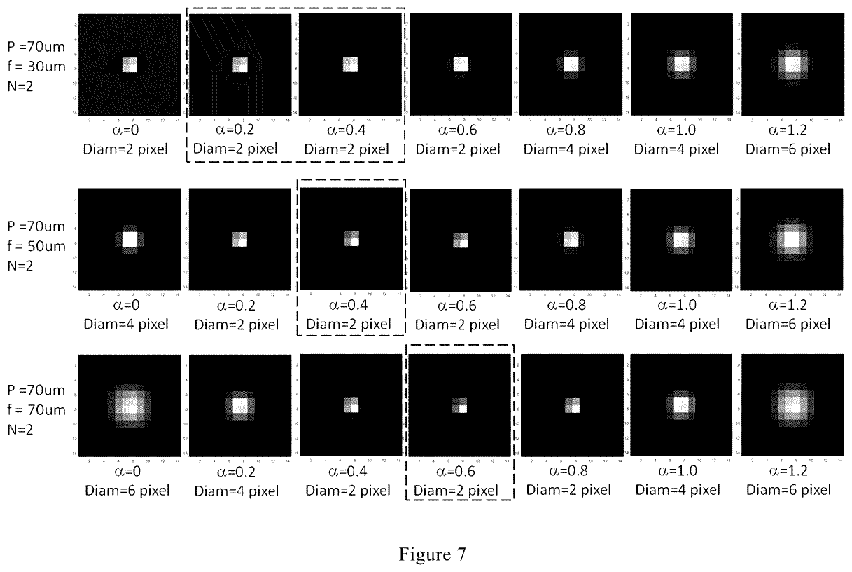

In Data Example 4, the working wavelength α=940 nm; the illumination light source 11 and the micro-lens array 12 are both rectangular arrays, where P=70 μm, W=70 μm; N=2; the focal length f of the micro-lens 12a takes values of 30 μm, 50 μm, and 70 μm, and α takes values of 7 points equally spaced from 0 to 1.2; diagrams of a single point light spot in the spot array light fields obtained by simulation calculation are shown in FIG. 7.

As shown in FIG. 7, corresponding to f=30 μm, when a takes values of 0, 0.2, 0.4, and 0.6, the diameter of a single light spot is of the minimum value, which is 2 pixels, and the midpoint α=0.3 can be taken as the optimal value in this case; corresponding to f=50 μm, when a takes values of 0.2, 0.4, and 0.6, the diameter of a single light spot is of the minimum value, which is 2 pixels, and the midpoint α=0.4 can be taken as the optimal value in this case; corresponding to f=70 μm, when a takes values of 0.4, 0.6 and 0.8, the diameter of a single light spot is of the minimum value, which is 2 pixels, and α=0.6 can be taken as the optimal value in this case. Being slightly different from FIGS. 3 and 5, FIG. 7 shows more clearly that under different parameter conditions, the optimal value of the coefficient α used for determining the working distance D₁ can be different. However, similar to that shown in FIGS. 3 and 5, it can be seen from FIG. 7 that, corresponding to f being 50 μm, as compared to the diameter (4 pixels) of the point light spot when α=0, when α takes a value of 0.4, the light spot on which the light energy of the spot array light field generated with the corresponding working distance D₁ is focused, is reduced to half the size; and corresponding to f being 70 μm, as compared to the diameter (6 pixels) of the point light spot when α=0, when α takes a value of 0.6, the light spot on which the light energy of the spot array light field generated with the corresponding working distance D₁ is focused, is reduced to one-third the size. This is beneficial to improving the contrast of the laser spot array.

FIG. 8 is a schematic diagram of a laser projection module according to Embodiment 2 of the present disclosure. The laser projection module 10′ shown in FIG. 8 has substantially the same structure and working mode as the laser projection module 10 shown in FIG. 1, that is, the laser projection module 10 and the laser projection module 10′ both comprise an illumination light source 11 and a micro-lens array 12, the micro-lens array 12 comprises a plurality of micro-lenses 12a arranged in an array in a plane, and when the micro-lens array 12 is at the working distance D₁ relative to the illumination light source 11, the laser projection module is in the working mode of projecting a spot array light field to project a spot array light field LF on a target surface 20 (see FIG. 1), wherein the working distance D₁ satisfies the following equation:

$${D}_{1} = \frac{{NP}^{2}}{2 λ} + α f$$

where N is a positive integer, preferably N≤5; λ is a wavelength of light from the illumination light source 11; α is a coefficient, 0<α≤1; and f is a focal length of the micro-lens 12a.

The difference between the laser projection module 10′ and the laser projection module 10 lies in that the laser projection module 10′ is further configured to have a working mode of projecting a uniform light field. In this working mode, the micro-lens array 12 has a working distance D₂ relative to the illumination light source 11, so that the light from the illumination light source 11 is modulated by the micro-lens array 12 to project a uniform light field on the target surface, where the working distance D₂ satisfies the following equation:

$${D}_{2} = \frac{{MP}^{2}}{2 λ} + \frac{β {P}^{2}}{4 λ} + α f$$

where M is a non-negative integer, β is a coefficient, and 0.8≤β≤1.2.

The term

$$\frac{β {P}^{2}}{4 λ}$$

in the above equation can be regarded as

$$( \frac{β}{2} ) \times \frac{{P}^{2}}{2 λ} \approx 0.5 \times \frac{{P}^{2}}{2 λ} .$$

This term makes the working distance D₂ deviate from the working distance D₁ as much as possible (when N takes different integers, D₁ can take different values having an interval of substantially

$$\frac{{P}^{2}}{2 λ} ) ,$$

so that the micro-lens array 12 can play a better role in diffusing and homogenizing the light from the illumination light source 11, thereby realizing the projection of the uniform light field.

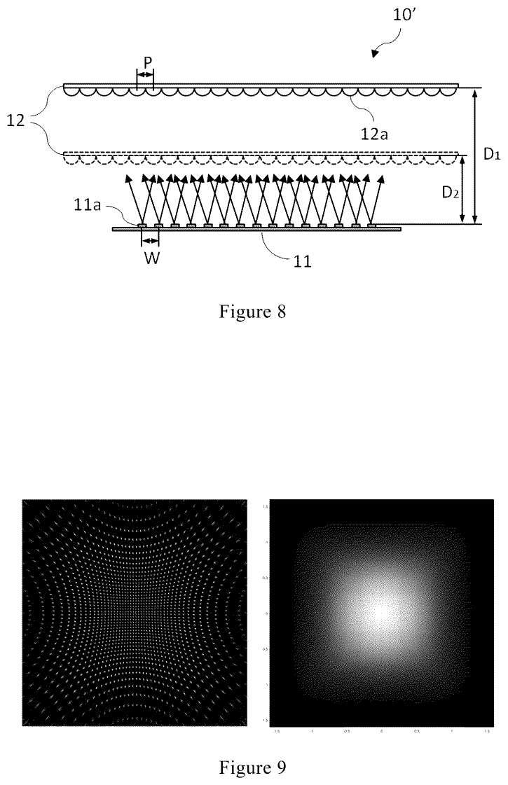

Only for purpose of illustration, FIG. 9 shows examples of simulation diagrams of a spot array light field and a uniform light field obtained based on the laser projection module 10′ shown in FIG. 8.

Preferably, as shown in FIG. 8, in the laser projection module 10′, the working distance D₂ is less than the working distance D₁ to avoid increasing the thickness of the module.

In the example shown in FIG. 8, the micro-lens array 12 is shown to be movable along a direction perpendicular to a plane in which the micro-lens array 12 lies, so as to switch between the working distance D₁ for projecting a spot array light field and the working distance D₂ for projecting a uniform light field, relative to the illumination light source 11. This can be achieved, for example, by providing in the laser projection module 10′ a linear motor or other electromagnetic actuation mechanism for driving the micro-lens array 12 to move, or even by providing manual actuation and limiting structures for the micro-lens array 12. It should be understood that the laser projection module 10′ according to the present embodiment is not limited to moving the micro-lens array 12, and it can also be configured to achieve the switching of the working distance by moving the illumination light source 11 or moving both the illumination light source 11 and the micro-lens array 12, thereby switching the working modes.

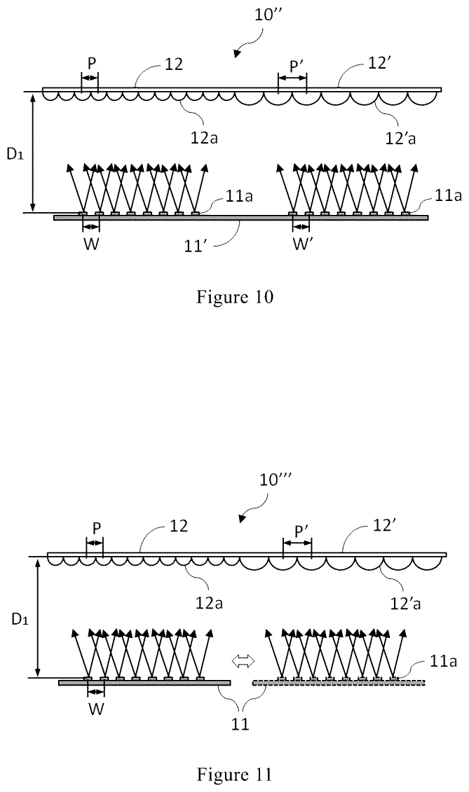

FIG. 10 is a schematic diagram of a laser projection module according to Embodiment 3 of the present disclosure. The laser projection module 10″ shown in FIG. 10 comprises an illumination light source 11′ and two micro-lens arrays, namely a first micro-lens array 12 and a second micro-lens array 12′, wherein the first micro-lens array 12 and the illumination light source 11′ have the same structure and satisfy the same equation as those of the micro-lens array and the illumination light source in the laser projection module 10 according to Embodiment 1 of the present disclosure, especially, having a working distance D₁ between them for projecting a spot array light source. The details can be found in the introduction above and will not be repeated here.

As shown in FIG. 10, the second micro-lens array 12′ comprises a plurality of micro-lenses 12′a arranged in the same plane as the first micro-lens array 12. The plurality of micro-lenses 12′a are arranged in an array at a predetermined pitch P′, which is different from the arrangement pitch P of the micro-lenses 12a in the first micro-lens array 12, so that the light from the illumination source 11′ is modulated by the second micro-lens array 12′ and projected on the target surface as a uniform light field.

Preferably, the pitch P′ in the second micro-lens array 12′ satisfies the following equation:

$${D}_{1} = \frac{{M}^{′} {P}^{′2}}{2 λ} + \frac{{β}^{′} {P}^{′2}}{4 λ} + {α}^{′} {f}^{′}$$

where, M′ is a non-negative integer; f′ is a focal length of the second micro-lens 12′a; α′ is a coefficient, 0<α′≤1; and β′ is a coefficient, 0.8≤β′≤1.2.

In the example shown in FIG. 10, the illumination light source 11′ has two light source groups corresponding to the first micro-lens array 12 and the second micro-lens array 12′, respectively, and the two light source groups are shown to have different light source spacings W and W′, so as to cooperate with different micro-lens arrays to achieve better spot array light field and uniform light field. In some implementations, the first micro-lens array and the second micro-lens array can have different array forms, such as a rectangular array and a regular hexagonal array, respectively.

It should be understood that the above example is merely illustrative but not restrictive. For example, corresponding to two micro-lens arrays, the illumination light source 11′ can have uniform and consistent light source configurations, for example, having the same array form and/or the same light source spacing.

FIG. 11 is a schematic diagram of a variant of the laser projection module shown in FIG. 10. A laser projection module 10″ shown in FIG. 11 has a structure substantially the same as that of the laser projection module 10″ shown in FIG. 10, except that the laser projection module 10′″ is configured such that the illumination light source 11 can move relative to the first micro-lens array 12 and the second micro-lens array 12′ in parallel to a plane in which the first micro-lens array 12 and the second micro-lens array 12′ lie, so that in a working mode of projecting a spot array light field, the illumination light source 11 faces the first micro-lens array 12, while in a working mode of projecting a uniform light field, the illumination light source 11 faces the second micro-lens array 12′.

It should be understood that in other implementations, the laser projection module 10″′ can also be configured to switch the above working modes by moving the micro-lens array or both the micro-lens array and the illumination light source.

The above description is merely an illustration of the preferred embodiments of the present application and the applied technical principles. Those skilled in the art should understand that the scope of the disclosure involved in the present application is not limited to the technical solution formed by the specific combination of the above technical features, but also covers other technical solutions formed by any combination of the above technical features or their equivalent features without departing from the inventive concept. For example, the technical solution is formed by replacing the above features with (but not limited to) the technical features with similar functions disclosed in the present application.

1. A laser projection module based on micro-lens array, comprising:
an illumination light source; and
a first micro-lens array, wherein the first micro-lens array comprises a plurality of first micro-lenses arranged in a first plane, the plurality of first micro-lenses are arranged in a first array at a first pitch P,
wherein the laser projection module is configured to have a first working mode; and
in the first working mode, in a direction perpendicular to the first plane, the first micro-lens array has a first working distance D₁ relative to the illumination light source, and light from the illumination light source is modulated by the first micro-lens array to project a spot array light field on a target surface,
the first working distance D₁ satisfies the following equation:
$${D}_{1} = \frac{{NP}^{2}}{2 λ} + α f$$
where N is a positive integer, preferably N≤5; λ is a wavelength of light from the illumination light source; α is a first coefficient, 0<α≤1; and f is a focal length of the first micro-lens.

2. The laser projection module of claim 1, wherein the first micro-lens has an aspherical surface and has focal lengths f₁ and f₂ in two mutually perpendicular directions in the first plane, respectively, where f=(f₁+f₂)/2.

3. The laser projection module of claim 1, wherein the first array is a rectangular array, a parallelogram array, or a regular hexagonal array.

4. The laser projection module of claim 1, wherein the illumination light source comprises a plurality of light-emitting points arranged in a second plane, the second plane is parallel to the first plane, and the plurality of light-emitting points are arranged in a light source array at a light source spacing W, and cell structures of the light source array are polygons similar to cell structures of the first array.

5. The laser projection module of claim 4, wherein the first pitch P and the light source spacing W satisfy the following equation:
$$wW = pP$$
where w and p are positive integers without a common factor, and preferably, w=p=1.

6. The laser projection module of claim 1, wherein the laser projection module is further configured to have a second working mode; and
in the second working mode, in a direction perpendicular to the first plane, the first micro-lens array has a second working distance D₂ relative to the illumination light source, and light from the illumination light source is modulated by the first micro-lens array to project a uniform light field on a target surface,
wherein the second working distance D₂ satisfies the following equation:
$${D}_{2} = \frac{{MP}^{2}}{2 λ} + \frac{β {P}^{2}}{4 λ} + α f$$
where M is a non-negative integer, β is a second coefficient, and 0.8≤β≤1.2.

7. The laser projection module of claim 6, wherein the second working distance is smaller than the first working distance.

8. The laser projection module of claim 6, wherein the laser projection module is configured such that at least one of the illumination light source and the first micro-lens array is movable in a direction perpendicular to the first plane, so that the first micro-lens array switches between the first working distance and the second working distance relative to the illumination light source.

9. The laser projection module of claim 1, further comprising:
a second micro-lenses array, the second micro-lenses array comprising a plurality of second micro-lenses arranged in the first plane, the plurality of second micro-lenses being arranged in a second array at a second pitch P′,
wherein the laser projection module is further configured to have a second working mode; and in the second working mode, light from the illumination source is modulated by the second micro-lens array to project the uniform light field on the target surface.

10. The laser projection module of claim 9, wherein the second pitch P′ satisfies the following equation:
$${D}_{1} = \frac{{M}^{′} {P}^{′2}}{2 λ} + \frac{{β}^{′} {P}^{′2}}{4 λ} + {α}^{′} {f}^{′}$$
where, M′ is a non-negative integer; f′ is a focal length of the second micro-lens; α′ is a third coefficient, 0<α′≤1; and β′ is a fourth coefficient, 0.8≤β′≤1.2.

11. The laser projection module of claim 9, wherein, in the first working mode, the illuminating light source faces the first micro-lens array; and in the second working mode, the illuminating light source faces the second micro-lens array.

12. The laser projection module of claim 11, wherein the laser projection module is configured such that the illumination light source is movable parallel to the first plane and relative to the first micro-lens array and the second micro-lens array.

13. The laser projection module of claim 5 wherein the laser projection module is further configured to have a second working mode; and
in the second working mode, in a direction perpendicular to the first plane, the first micro-lens array has a second working distance D₂ relative to the illumination light source, and light from the illumination light source is modulated by the first micro-lens array to project a uniform light field on a target surface,
wherein the second working distance D₂ satisfies the following equation:
$${D}_{2} = \frac{{MP}^{2}}{2 λ} + \frac{β {P}^{2}}{4 λ} + α f$$
where M is a non-negative integer, β is a second coefficient, and 0.8≤β≤1.2.

14. The laser projection module of claim 13, wherein the second working distance is smaller than the first working distance.

15. The laser projection module of claim 13, wherein the laser projection module is configured such that at least one of the illumination light source and the first micro-lens array is movable in a direction perpendicular to the first plane, so that the first micro-lens array switches between the first working distance and the second working distance relative to the illumination light source.

16. The laser projection module of claim 5, further comprising:
a second micro-lenses array, the second micro-lenses array comprising a plurality of second micro-lenses arranged in the first plane, the plurality of second micro-lenses being arranged in a second array at a second pitch P′,
wherein the laser projection module is further configured to have a second working mode; and in the second working mode, light from the illumination source is modulated by the second micro-lens array to project the uniform light field on the target surface.

17. The laser projection module of claim 16, wherein the second pitch P′ satisfies the following equation:
$${D}_{1} = \frac{{M}^{′} {P}^{′2}}{2 λ} + \frac{{β}^{′} {P}^{′2}}{4 λ} + {α}^{′} {f}^{′}$$
where, M′ is a non-negative integer; f′ is a focal length of the second micro-lens; α′ is a third coefficient, 0<α′≤1; and β′ is a fourth coefficient, 0.8≤β′≤1.2.

18. The laser projection module of claim 17, wherein, in the first working mode, the illuminating light source faces the first micro-lens array; and in the second working mode, the illuminating light source faces the second micro-lens array.

19. The laser projection module of claim 17, wherein the laser projection module is configured such that the illumination light source is movable parallel to the first plane and relative to the first micro-lens array and the second micro-lens array.
